(19) United States
(12) Patent Application Publication
(10) Pub. No.: US 2010/0164083 A1
(43) Pub. Date: Jul. 1, 2010

(54) PROTECTIVE THIN FILM COATING IN CHIP PACKAGING

(75) Inventor: Myung Jin Yim, Chandler, AZ (US)

Correspondence Address: Gerbera/BSTZ;Blakely Sokoloff Taylor & Zafman LLP, 1279 OAKMEAD PARKWAY, SUNNYVALE, CA, 94085, US

(73) Assignee: Numonyx B.V., Rolle (CH)

(21) Appl. No.: 12/345,572

(22) Filed: Dec. 29, 2008

(51) Int. Cl. H01L 23/02; H01L 21/52; H01L 23/48

(52) U.S. Cl. 257/686; 438/114; 257/701; 257/693; 438/109; 257/E21.5; 257/E23.18; 257/E21.506

(57) ABSTRACT

A protective thin film coating for device packaging. A dielectric thin film coating is formed over die and package substrate surfaces prior to applying a molding compound. The protective thin film coating may reduce moisture penetration from the bulk molding compound or the interface between the molding compound and the die or substrate surfaces.

### TECHNICAL FIELD

Embodiments of the invention are in the field of microelectronic assembly, more specifically pertaining to materials formed over a microelectronic chip mounted to a package substrate.

### BACKGROUND

A microelectronic package may use a package substrate to deliver power from a power supply and signals from outside the package to a microelectronic chip or die. A package substrate may be connected to a microelectronic die using a molded matrix array package (MMAP) process.

There are moisture related reliability concerns for such molded packages during packaging reliability testing. Under conditions of high temperature and high humidity, moisture may be absorbed into the plastic molding compounds and die attach adhesive materials typically used in molded packages. As a result, molded packages may fail conditions in a bias HAST (Highly Accelerated Stress Test). Such failures incurred at the package level are extremely costly.

This problem is exacerbated by the industry trend toward stacked-die chip-scale packages (SCSPs) to provide higher performance while consuming nearly the same footprint as conventional single-die packages. Because SCSPs combine two or more ICs, both the odds and cost of a moisture-based package reliability failure are higher than for single-die packages. With the number of die integrated into an SCSP increasing, methods for reducing moisture-based package reliability failures become all the more important.

### BRIEF DESCRIPTION OF THE DRAWINGS

Embodiments of the present invention are illustrated by way of example, and not limitation, in the figures of the accompanying drawings in which:

FIG. 1 illustrates a flow diagram of a method of forming a thin film in a die package, in accordance with an embodiment of the present invention;

FIG. 2A illustrates a cross-sectional view representing a particular operation in a packaging process in which a microelectronic die is attached to a package substrate and wire bonded, in accordance with an embodiment of the present invention;

FIG. 2B illustrates a cross-sectional view representing a particular operation in a packaging process in which a microelectronic die is stacked onto another microelectronic die and wire bonded, in accordance with an embodiment of the present invention;

FIG. 2C illustrates a cross-sectional view representing a particular operation in a packaging process in which a microelectronic die is attached to a package substrate with solder balls, in accordance with an embodiment of the present invention;

FIG. 3A illustrates a cross-sectional view representing a particular operation in a packaging process in which a conformal thin film is formed on a microelectronic die attached to a package substrate, such as that depicted in FIG. 2A, in accordance with an embodiment of the present invention;

FIG. 3B illustrates a cross-sectional view representing a particular operation in a packaging process in which a conformal thin film is formed on a microelectronic die attached to a package substrate, such as that depicted in FIG. 2B, in accordance with an embodiment of the present invention;

FIG. 3C illustrates a cross-sectional view representing a particular operation in a packaging process in which a conformal thin film is formed on a microelectronic die attached to a package substrate, such as that depicted in FIG. 2C, in accordance with an embodiment of the present invention;

FIG. 4 illustrates a cross-sectional view representing a particular operation in a packaging process in which a molding compound is formed over the conformal thin film formed on a microelectronic die, such as that depicted in FIG. 3A, in accordance with an embodiment of the present invention; and

FIG. 5 illustrates a cross-sectional view representing a particular operation in a packaging process in which a molded matrix array package is singulated, in accordance with an embodiment of the present invention.

### DETAILED DESCRIPTION

Embodiments of a method for reducing moisture penetration into active metallization pad areas are described herein with reference to figures. Particular embodiments may be practiced without one or more of the specific details described, or in combination with other known methods, materials, and apparatuses. In the following description, numerous specific details are set forth, such as specific materials, dimensions and processes parameters etc. to provide a thorough understanding of the present invention. In other instances, well-known microelectronic design and packaging techniques have not been described in particular detail to avoid unnecessarily obscuring the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

The terms “over,” “under,” “between,” and “on” as used herein refer to a relative position of one structure or layer with respect to other structures or layers. As such, for example, one layer deposited or disposed over or under another may be directly in contact with the other layer or may have one or more intervening layers. Moreover, one layer deposited or disposed between layers may be directly in contact with the layers or may have one or more intervening layers. In contrast, a first layer or structure “on” a second layer or structure is in contact with that second layer or structure. Additionally, the relative position of one structure with respect to other structure is provided assuming operations deposit, modify and remove films relative to a starting substrate without consideration of the absolute orientation of the substrate.

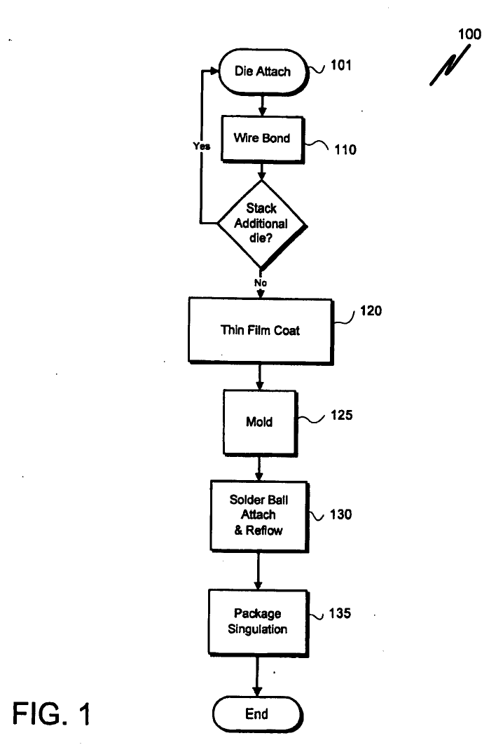

FIG. 1 illustrates a flow diagram depicting a sequence of particular operations employed in a wire bonding molded matrix array package (WB-MMAP) method 100, in accordance with embodiments of the present invention. Generally, the WB-MMAP method 100 exemplifies use of a conformal thin film coating formed on microelectronic die, such as an integrated circuit (IC) memory device, an application specific IC (ASIC), a micro-electro-mechanical system (MEMS), or the like. The techniques described in the context of the WB-MMAP method 100 are also adaptable to other packaging methods utilizing similar materials, such as a flip-chip (e.g., controlled collapse chip connection, or “C4”) to achieve a similar benefit.

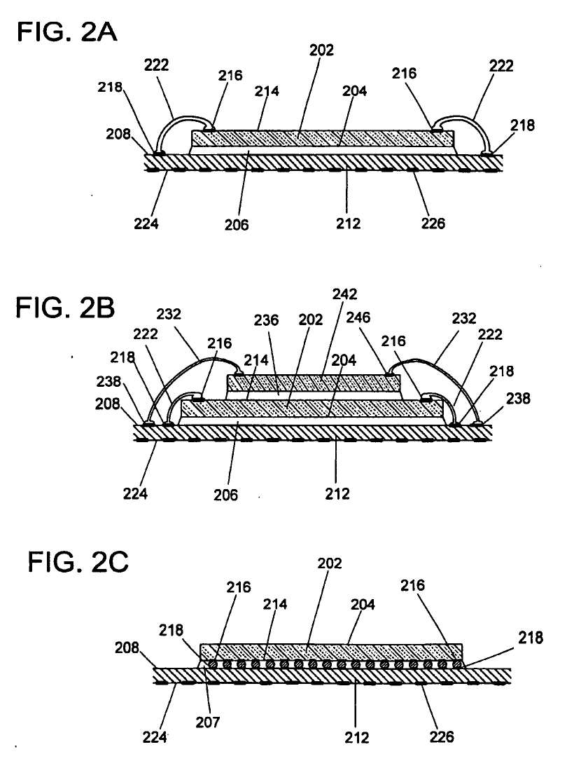

WB-MMAP method 100 begins at the die attach operation 101. During the die attach operation 101 a microelectronic die, typically having been thinned with a back side grind (BSG) and polish process, is attached to a package substrate. FIG. 2A illustrates a cross-sectional view representing a particular operation in an exemplary packaging process in which a microelectronic die 202 is attached to a package substrate 212. The microelectronic die 202 may be an ASIC, a microprocessor, or the like. In at particular embodiment, however the microelectronic die 202 is a memory device including a memory array, such as flash memory array, a phase change memory (PCM) array, a MRAM array or a FRAM array.

The package substrate 212 provides a larger area to distribute signals from the microelectronic die 202, as well as providing physical protection and support for the thinned die. The package substrate 212 may include any materials employed in the art for such purposes and in one embodiment is constructed from a composite material. In an embodiment, the package substrate 212 is a multi-layer substrate having at least ground plane and a power plane. The package substrate 212 may further include a number of vias (not shown) to facilitate vertical electrical signal travel within the package substrate. For example, a substrate via may extend from a metallized substrate bond pad 218 on the substrate top side 208 to a substrate ball limiting metallurgy (BLM) pad 226 on the substrate bottom side 224. The metallized substrate bond pad 218 and BLM pad 226 may be of any metal commonly employed in the art for such purposes (e.g., copper, titanium, aluminum, etc.).

During the die attach operation 101, the die backside 204 is adhered to the substrate top side 208 with a die attach material 206. The die attach material 206 may be a paste, a die-attach film (DAF) or a dicing die-attach film (DDF) applied to the die backside 204. In certain embodiments (die attach paste or DDF), the die attach material 206 is a composite including an epoxy resin and glass or polymer organic spheres to provide good bond line thickness control at a desired thickness. Depending die attach method, the die attach operation 101 may further include a cure (e.g., for paste attach). Additionally, the die attach operation 101 may include a post-die attach plasma clean using an oxidizing or reducing chemistry to remove organic residues from the non-bonded surfaces of the microelectronic die 202 and package substrate 212. Such a clean advantageously prepares metallized bond pads, such as the metallized substrate bond pad 218, for wire bonding.

FIG. 2C depicts an alternate embodiment where the microelectronic die 202 is attached to the package substrate 212 in a flip-chip configuration. In such an embodiment, during a die attach operation analogous to the die attach operation 101, the die frontside 214 is attached to the substrate top side 208 with solder joints 256 between the metallized die bond pad 216 and the metallized substrate bond pad 218. An underfill material 207 is then applied to fill voids between the solder joints 256. Any commercially available solder, such as a tin/lead alloy, may be used for the solder joints 256. Similarly, any commercially available underfill material 207, such as one comprising an epoxy resin, may be utilized.

Returning to FIG. 1, following the die attach operation 101, the WB-MMAP method 100 proceeds to a wire bond operation 110. During this operation, as further shown in FIG. 2A, one or more bonding wires 222 are attached between the microelectronic die 202 and the package substrate 212 to allow electrical communication between the metallized substrate bond pad 218 and a metallized die bond pad 216 on the die frontside 214. The metallized die bond pad 216 may be of any metal commonly used in the art, such as any of those previously described for the metallized substrate bond pad 218). As depicted, the bonding wires 222 are attached the metallized bond pads 216 and 218. In a particular embodiment, the bonding wires 222 have pitch of less than 60 microns and employ wires with a diameter of less than 25 microns. The bonding wires 222 may be of any conventional wire material, for example copper or aluminum. However, in a particularly advantageous embodiment, the primary constituent of the bonding wires 222 is gold.

As further depicted in FIG. 1, following the wire bond operation 110, if additional die are to be integrated into a same package as the microelectronic die 202 (e.g., for a SCSP), then the WB-MMAP method 100 returns to the die attach operation 101. Another die, such as the overlying microelectronic die 242 depicted in FIG. 2B, is then attached to the microelectronic die 202 with a layer of die attach material 236 there between. Any stacking method commonly known in the art may be applied. In the exemplary embodiment depicted, a pyramid die stack is formed. Other embodiments include disposing one or more microelectronic die over the first microelectronic die 202 to form a shingle stack, orthogonal stack, or other commonly know die stack configuration. Any of the die attach materials and methods previously described for the die attach operation 101 may be repeated with minor modifications to stack the additional die. Similarly, in further embodiments where at least one microelectronic die is stacked over the microelectronic die 202, the wire bond operation 110 is repeated substantially as previously described to connect a bonding wire 232 between a metallized die bond pad 246 and a metallized substrate bond pad 238.

Following the wire bond operation 110, the WB-MMAP method 100 proceeds to a thin film coat operation 120. In certain embodiments, prior to forming the thin film, a plasma clean using an oxidizing or reducing chemistry may be performed to clean residues left behind by the wire bond operation 110. A plasma clean may improve adhesion between the subsequently deposited thin film and the microelectronic die, package substrate and bond wires.

Generally, the thin film is formed over surfaces of microelectronic die(s), bond wire(s), die attach film(s) and package substrate such that a moisture barrier is created around package regions susceptible to moisture. The thin film is of a material and is formed in a manner to reduce moisture penetration into these package regions.

It has been found that the moisture absorbed into the molding and die attaching materials increases the mobility of certain ions, such as a copper-II ion originating from, for example, the metallized die bond pad 216 and/or metallized substrate bond pad 218. Copper dendrite growth which eventually electrically shorts I/O pads of the packaged microelectronic die has been attributed to this higher ion mobility. While the microelectronic die 202 will typically include a passivation layer, the metallized die bond pad 216 is free of such passivation to allow for wire bonding and therefore remains an active surface within the package. The thin film reduces moisture penetration into such active sources and sinks of such mobile ions, reducing copper electrochemical migration failures and improving package reliability.

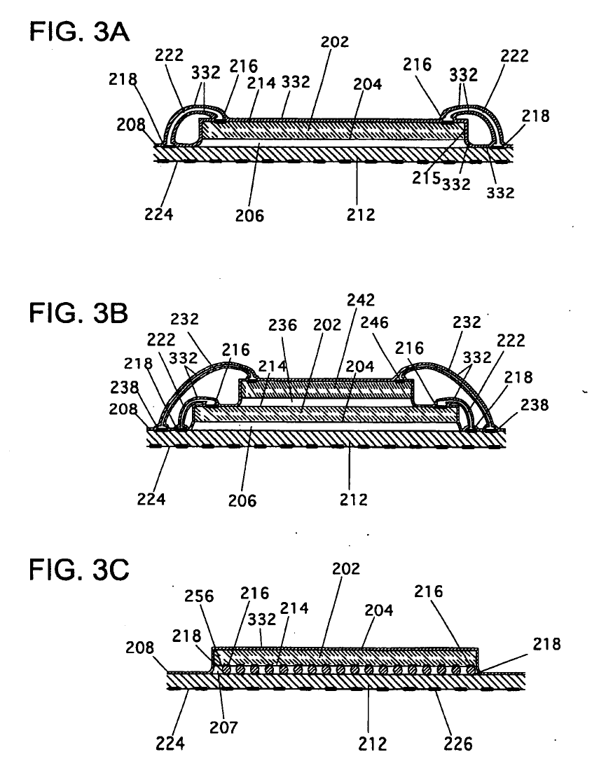

In an embodiment, as depicted in FIG. 3A, a thin film 332 is formed over the microelectronic die 202 to cover the exposed die frontside 214, specifically the metallized die bond pad 216. While the embodiment depicted in FIG. 3A illustrates how the thin film 332 is formed on the single die embodiment of FIG. 2A, stacked die embodiments may be similarly coated with the thin film using the techniques described herein to form a moisture barrier surrounding additional bond wires, covering additional metallized die bond pads, and covering additional substrate bond pads. For example, as depicted in FIG. 3B, the thin film 332 surrounds the bonding wires 222 and 232, covers the metallized die bond pads 216 and 246 and covers the metallized substrate bond pads 218 and 238. As shown, the thin film 332 also covers the die attach material 236 between the microelectronic die 202 and an overlying microelectronic die 242, as well as the top surface of the overlying microelectronic die 242.

FIG. 3C illustrates an exemplary flip-chip embodiment, where the intermediate package structure depicted in FIG. 2C is coated with the thin film 332. In this embodiment, the thin film 332 is applied onto the microelectronic die 202 to cover the exposed die backside 204. For such flip-chip embodiments, there may or may not be any metallization on the backside 204. For example, in certain embodiments where the microelectronic die 202 has been processed to have through vias, metallization is present on the die backside 204. In situations where there is metallization on the die backside 204, wire bond connections may be made to the package substrate 212 substantially as described for FIG. 2A or solder joints may be made between the die backside 204 and another microelectronic die or board substantially as described for solder joints 256. In either event, the thin film 332 is subsequently deposited to protect these metallized connections. In situations where there is no metallization on the die backside 204, the thin film 332 functions as a moisture barrier protecting the solder joints 256 and the underfill material 207 from external moisture sources.

For any of the exemplary embodiments depicted in FIG. 3A, FIG. 3B or FIG. 3C, the thin film 332 is substantially conformal to remain substantially continuous over topographic features and to also completely surround or encase the bonding wires 222. As used herein, “conformal” refers to a structural condition where a thickness of a film is independent of the orientation of the surface upon which the film is deposited. For example, the thickness of a substantially conformal film covering all sides of a three dimensional structure is substantially equal for all surfaces. Because the thin film 332 is a dielectric and conformally coats the bonding wires 222, failures associated with wire sweep may also be prevented. Wire sweep is a phenomenon where application of a molding compound induces stress which deforms bonding wires and causes them to short to one another. As the trend of decreasing bonding wire diameter and increasing bonding wire length for finer pitch, wire sweep is increasing critical failure of the mold process. Because of the conformality and limited thickness of the thin film 332, the bonding wires 222 may be completely coated such that no short can form even if wire sweep occurs.

As further shown in FIG. 3A, the thin film 332 is also formed over the metallized substrate bond pad 218. Embodiments where the metallized substrate bond pad 218 is sealed with the thin film 332 are particular advantageous for SCSP, where one metallized substrate bond pad 218 may be minimally spaced apart from another to accommodate a high density of bonding wires (making I/O shorts on the package substrate 212 more likely).

In this manner, the thin film 332 may prevent substantially any contact between metallized surfaces and a subsequently formed molding compound. This is particularly advantageous where a metallized surface has a low density of bonding states (e.g., a gold surface) and adheres poorly to molding compounds. It has been found that the free volume present in a poorly adhered interface sinks moisture present in the molding compound bulk. For embodiments where the thin film 332 conformally coats gold bonding wires, moisture adsorption and migration along the length of the bonding wires is reduced.

In a further embodiment the thin film 332 also covers the die sidewall 215, the sidewalls of the die attach material 206, and covers the substrate top side 208 to reduce moisture penetration into these surfaces. Sealing the die sidewall 215 with the thin film 332 reduces moisture penetration where a die passivation layer is breached during die saw and improves the integrity of the die edge seal. Sealing both the die sidewall 215 and the die attach material 206 with the thin film 332 is particularly advantageous for SCSP to reduce moisture penetration into the active die and bonded interfaces within a die stack. For example, die attach material in a film over wire (FOW) die stack may not completely cover a wire bond or may be of a porous or hygroscopic material which benefits from sealing. Similarly, sealing the substrate top side 208 with the thin film 332 reduces moisture penetration into the metallization layers of a multi-layered substrate (e.g., inter-layer vias, etc.). Additionally, the thin film 332 adheres to solder resists (not depicted) surrounding metallized regions such as the metallized die bond pad 216 and metallized substrate bond pad 218. In certain embodiments, and as depicted in FIG. 3, the thin film 332 is not formed on the substrate bottom side 224.

In the exemplary embodiment depicted in FIG. 3A, the thin film 332 is on (i.e., in contact with) each of: the die frontside 214; the die sidewall 215; the substrate top side 208; the bonding wires 222; the metallized die bond pad 216; and metallized substrate bond pad 218. However, one or more other materials may be present between the thin film 332 and any one of these same surfaces without detracting from the ability of the thin film 332 to resist penetration of moisture external to the thin film 332 (e.g., within a subsequently formed molding compound). Embodiments with one or more intervening films between the depicted surfaces and the thin film 332 are therefore possible.

Generally, to serve as a good moisture barrier, the thin film 332 should have a low porosity, for example less than 5%. In particularly advantageous embodiments, the porosity is below 1%. In a further embodiment, the thin film 332 is substantially free of pin holes (voids spanning the thickness of the film).

In one embodiment, the thin film 332 is an inorganic material including alumina (Al₂O₃). In a particular embodiment, alumina is the primary constituent of the thin film 332. In a further embodiment, an alumina-based inorganic material is deposited by atomic layer deposition (ALD) at approximately room temperature (i.e., 25° C.). In one such embodiment the ALD alumina film is deposited to a thickness of approximately 10 nanometers (nm) and 300 nm. ALD alumina has the advantages of being highly conformal, providing good electrical insulation, having essentially 0% porosity, pin hole free at very low thickness, and may be deposited at low temperatures.

It is advantageous to employ low temperature processes for the formation of the thin film 332 because at the thin film coat operation 120, the microelectronic die 202 has been attached and wire bonded to the package substrate 212 and variations in the temperature may cause a resultant differential expansion between the chip and the package substrate. The differential expansion may induce stresses that can cause the connections between the chip and the package substrate to fail (e.g., crack one or more wire bonds).

ALD alumina films also provide high adhesion strength with the polymer resin materials, such as those which may be found on the package substrate top side 208 and in the die attach material 206. Furthermore, a subsequently formed molding compound will also adhere well to the ALD alumina. The thin film 332 may be formed using any ALD alumina process commonly known in the art and therefore a detailed listing of process parameters is not provided.

In an alternative embodiment, the thin film 332 is parylene Type N, C, D, or F. Parylene is a commonly used name for poly-(para-xylenes). In a particularly advantageous embodiment, the thin film 332 is parylene deposited by chemical vapor deposition (CVD) at approximately 25° C. Like ALD, CVD has the advantage of being a vapor phase deposition which is capable of much thinner films than are most non-vapor phase depositions (e.g., liquid phase). CVD parylene is also substantially free of pinholes at such thickness and provides a hydrophobic layer with good adhesion characteristics. Vapor-phase deposition techniques are also advantageous because they can be solvent free. CVD parylene processes are generally sub-atmospheric, but are at pressures high enough that the deposition is non-line of sight and therefore can be made highly conformal. In one such embodiment the CVD parylene film is deposited to a thickness of approximately 10 nanometers (nm) and 300 nm. Low temperature parylene CVD processes are commercially available and therefore a detailed listing of process parameters is not provided herein.

In other embodiments, the thin film 332 is a polyimide (PI), a polyalkene (polyolefin), or benzocyclobutene (BCB). For such embodiments, these materials may be applied at low temperatures using either a spray coating process or sub-atmospheric CVD. Exemplary spray coating embodiments employ nanoparticle mass flow deposition techniques, such as aerosol deposition (AD). Nanoparticle mass flow deposition is distinguished from thermal spray processes by the smaller size of the particles deposited onto a substrate. For example, a particular aerosol deposition processes utilizes particles in the range of 10 nm-1 μm in diameter. Nanoparticle mass flow deposition is typically also performed at a low temperature (nanoparticles are not melted or softened). In one such embodiment, the PI, polyalkene or BCB is applied to a thickness between approximately 1 μm and 10 μm. Alternatively, PI may be formed with low temperature CVD process, for example by co-evaporation of dianhydride and diamine monomers. BCB may also be deposited by low temperature plasma enhanced CVD (PECVD).

In other embodiments, the thin film 332 is an epoxy, a room temperature vulcanized (RTV) silicone, a fluorinated silicone (e.g., polysiloxanes), a fluorinated acrylic or a polyurethane. For such embodiments, these materials may be applied at low temperature using a spray coating process, such as an AD. Sol-gel methods may also be employed. In particular embodiments, the epoxy, RTV silicone, fluorinated silicone, fluorinated acrylic or polyurethane is deposited at a temperature of approximately 25° C. to a thickness of approximately 1 μm-100 μm. Generally, the smallest thickness that can be controlled and is substantially pinhole free is preferred to ensure conformality of the thin film 332. In particular embodiments, AD is employed to form the thin film 332 to a thickness of approximately 1 μm-10 μm.

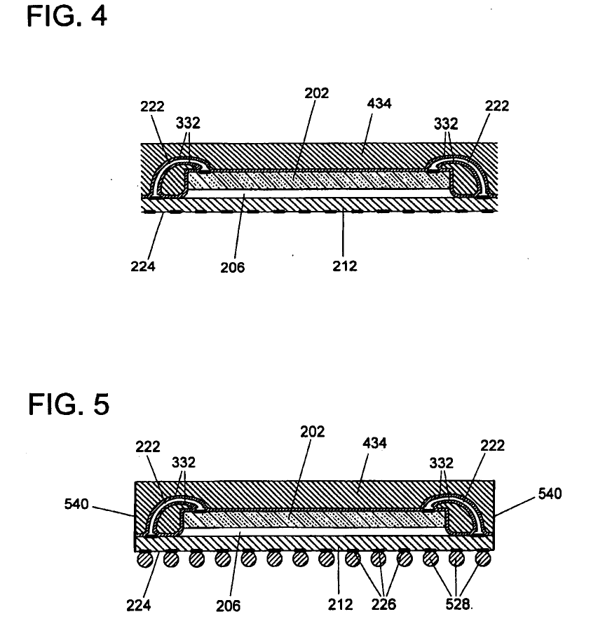

Returning to FIG. 1, at the mold operation 125, a molding compound is applied over the protective thin film coating. FIG. 4 illustrates the progression of the packaging from the intermediate structure depicted in FIG. 3A. As shown, a molding compound 434 is disposed over the microelectronic die 202, over the package substrate 212 and substantially surrounding the bonding wires 222. The thin film 332 forms a moisture barrier between each of these active package structures and the molding compound 434. As previously described, the thin film 332 protects the microelectronic die 202 and the package substrate 212 from moisture introduced into either the bulk of the molding compound 434 or along the interface between the molding compound 434 and the thin film 332. Ideally, because of the thin film 332, little if any metallized surface area of the microelectronic die 202, bonding wires 222 or package substrate 212 is in contact with the molding compound 434. Additionally, for flip-chip embodiments (e.g., as depicted in FIG. 3C), the thin film 332 similarly protects the solder joints 256 and the underfill material 207 between the microelectronic die 202 and the package substrate 212 form moisture in a surrounding molding compound (not depicted).

As depicted in FIG. 4, the microelectronic die 202 mounted to the package substrate 212 and protected by the thin film 332 is overmolded with the molding compound 434 to provide a level of protection from the external environment. A typical overmolding process places a solid or semi-solid molding compound over the microelectronic die 202 using a mold press. The package is then transferred through a heated mold that causes the molding compound to flow and encapsulate the chip. Generally, the molding compound is of a material having a higher organic content than any of the materials utilized for the thin film 332. The molding compound 434 may be any commercially available molding compound, such as one employing epoxy resin and an amine-based or phenolic-based hardener. The molding compound 434 may further include fillers such as ceramics or silica. Any of the compositions of the thin film 332 described elsewhere herein will have good adhesion to those molding compounds commonly used in the art. For example, epoxy with methylene diamine hardener has been found to have good adhesion to polyimides, parylenes and alumina. Toughness for this system is provided by addition of elastomers such as long chain aliphatic silicone-functionalized epoxies.

Following application of the mold operation 125, the WB-MMAP method 100 proceeds to solder ball attach and reflow operation 130. As further depicted in FIG. 5, solder balls 528 are attached to the BLM pad 226 to form ball grid array (BGA) interconnects to the substrate bottom side 224. The solder balls 528 are then reflowed and allowed to cool. Completing the WB-MMAP method 100, a package singulation operation 135 forms separate individual packaged units from the package substrate 212 (which up to this point served as a contiguous support for parallel package processing). During the package singulation operation 135, a cut 540 is made through the molding compound 434 and the package substrate 212.

Thus, packaging of a device with a thin film layer between the microelectronic die and a molding compound has been disclosed. Although the present invention has been described in language specific to structural features or methodological acts, it is to be understood that the invention defined in the appended claims is not necessarily limited to the specific features or acts described. The specific features and acts disclosed are to be understood as particularly graceful implementations of the claimed invention in an effort to illustrate rather than limit the present invention.

1. A method of packaging a microelectronic die, comprising:
attaching a first side of the die to a first side of a package substrate;
forming a substantially conformal dielectric thin film over a second side of the die and over the first side of the package substrate; and
applying a molding compound over the substantially conformal dielectric thin film coating.

2. The method as in claim 1, further comprising:
bonding wires from the second side of the die to the first side of the package substrate before forming the substantially conformal dielectric thin film coating;
encasing the bonded wires in the substantially conformal dielectric thin film coating when the coating is formed over the die;
attaching solder balls to a second side of the package substrate after applying the molding compound; and
singulating the package substrate after attaching the solder balls.

3. The method as in claim 1, further comprising:
underfilling a region between the first side of the die and the first side of the package substrate before forming the substantially conformal dielectric thin film coating;
encasing the underfill in the substantially conformal dielectric thin film coating when the coating is formed over the die;
attaching solder balls to a second side of the package substrate after applying the molding compound; and
singulating the package substrate after attaching the solder balls.

4. The method as in claim 1, wherein forming the substantially conformal dielectric thin film coating further comprises conformally depositing, with vapor phase deposition process performed at approximately 25° C., a film to a thickness of between 10 nm and 300 nm.

5. The method as in claim 4, wherein a poly(para-xylene) is deposited with a sub-atmospheric chemical vapor deposition (CVD) process.

6. The method as in claim 4, wherein a material comprising primarily alumina is deposited with an atomic layer deposition (ALD) process.

7. The method as in claim 4, wherein at least one of a polyimide, a polyalkene, or BCB is deposited with a sub-atmospheric chemical vapor deposition (CVD) process.

8. The method as in claim 1, wherein forming the conformal dielectric thin film coating further comprises:
spraying an epoxy, a room temperature vulcanized (RTV) silicone, a fluorinated silicone, a fluorinated acrylic or a polyurethane.

9. The method as in claim 8, wherein the spraying is an aerosol deposition process forming the conformal dielectric thin film coating to a thickness of between 1 μm and 10 μm.

10. A method of packaging a memory chip, comprising:
attaching, with a first die attach material, a first memory chip to a first side of a package substrate;
bonding a first wire from a first bond pad on the first memory chip to a second bond pad on the first side of the package substrate;
attaching, with a second die attach material, a second memory chip to the first memory chip;
bonding a second wire from a third bond pad on the second memory chip to a fourth bond pad on the first side of the package substrate;
forming a substantially conformal dielectric thin film coating over both the first and second memory chip stack, adjacent to the first and second die attach materials, over the second and fourth bond pad, and encasing the first and second bonded wires;
applying a molding compound over the substantially conformal dielectric thin film coating to surround the substantially conformal dielectric thin film encasing the first and second bonding wires.

11. The method as in claim 10, wherein forming the substantially conformal dielectric thin film coating further comprises vapor phase deposition of a poly(para-xylene) or alumina to a thickness of approximately 10 nm to 300 nm.

12-20. (canceled)
